(19) United States
(12) Patent Application Publication
(10) Pub. No.: US 2012/0153356 A1
(43) Pub. Date: Jun. 21, 2012

(54) HIGH ELECTRON MOBILITY TRANSISTOR WITH INDIUM GALLIUM NITRIDE LAYER

(75) Inventor: Paul Saunier, Dallas, TX (US)

(73) Assignee: TRIQUINT SEMICONDUCTOR, INC., Hillsboro, OR (US)

(21) Appl. No.: 12/973,416

(22) Filed: Dec. 20, 2010

(51) Int. Cl. H01L 29/778; H01L 21/335

(52) U.S. Cl. 257/194; 438/172; 257/E29.246; 257/E21.403

(57) ABSTRACT

Disclosed embodiments include a high electron mobility transistor (HEMT) with an indium gallium nitride layer set as one of a plurality of barrier sublayers and methods for forming such a HEMT. Other embodiments are also be described and claimed.

### FIELD

Embodiments of the present disclosure relate generally to the field of high electron mobility transistors (HEMTs), and more particularly to HEMTs with an Indium Gallium Nitride layer.

### BACKGROUND

A high electron mobility transistor (HEMT) is a type of field-effect transistor (FET) in which a heterojunction is generally formed between two semiconductor materials of different bandgaps. In HEMTs, high mobility electrons are generally generated using, for example, a heterojunction of a highly-doped wide bandgap donor-supply layer and a non-doped narrow bandgap channel layer with no dopant impurities. The donor-supply layer may also be referred to as a barrier layer, while the channel layer may also be referred to as a buffer layer. Current in a HEMT is generally confined to a very narrow channel at the heterojunction. Current flows between source and drain terminals and is controlled by a voltage applied to a gate terminal.

Some HEMTs include an aluminum gallium nitride (AlGaN) barrier layer coupled with a gallium nitride (GaN) buffer layer. Current through such AlGaN/GaN HEMTs is determined by the aluminum concentration and the thickness of the AlGaN barrier layer. A first type of AlGaN/GaN HEMT may include an AlGaN barrier layer that is 180 angstroms (Å) thick with an aluminum concentration of 28% for a maximum current density of approximately 1.2 amperes per millimeter (A/mm) (7-8 watts per millimeter (W/mm) at 40 volts bias). A second type of AlGaN/GaN HEMT may include an AlGaN barrier layer that is 200 Å thick with an aluminum concentration of 20% for a maximum current density of approximately 0.8 A/mm. Performance of the first type of HEMT is generally considered superior, for example, has a higher power density and increased efficiency; however, it is also less reliable due to high stress generated at an interface of the barrier layer. The high stress may be due to the relatively high aluminum concentration resulting in a lattice mismatch between the barrier and buffer layers. Performance of the second type of HEMT is generally considered inferior; however, it is also considered more reliable due to less stress generated at the interface of the barrier layer.

### BRIEF DESCRIPTION OF THE DRAWINGS

Embodiments are illustrated by way of example and not by way of limitation in the figures of the accompanying drawings, in which like references indicate similar elements.

FIG. 1 schematically illustrates a cross-sectional view of a semiconductor device in accordance with various embodiments of the present disclosure.

FIG. 2 schematically illustrates a cross-sectional view of another semiconductor device in accordance with various embodiments of the present disclosure.

FIG. 3 illustrates a method for fabricating a semiconductor device on a semiconductor substrate in accordance with various embodiments of the present disclosure.

### DETAILED DESCRIPTION

Various aspects of the illustrative embodiments will be described using terms commonly employed by those skilled in the art to convey the substance of their work to others skilled in the art. However, it will be apparent to those skilled in the art that alternate embodiments may be practiced with only some of the described aspects. For purposes of explanation, specific devices and configurations are set forth in order to provide a thorough understanding of the illustrative embodiments. However, it will be apparent to one skilled in the art that alternate embodiments may be practiced without the specific details. In other instances, well-known features are omitted or simplified in order not to obscure the illustrative embodiments.

Further, various operations will be described as multiple discrete operations, in turn, in a manner that is most helpful in understanding the present disclosure; however, the order of description should not be construed as to imply that these operations are necessarily order dependent. In particular, these operations need not be performed in the order of presentation.

The phrase “in various embodiments” is used repeatedly. The phrase generally does not refer to the same embodiments; however, it may. The terms “comprising,” “having,” and “including” are synonymous, unless the context dictates otherwise.

In providing some clarifying context to language that may be used in connection with various embodiments, the phrases “A/B” and “A and/or B” mean (A), (B), or (A and B); and the phrase “A, B, and/or C” means (A), (B), (C), (A and B), (A and C), (B and C) or (A, B and C).

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled to each other.

In various embodiments, the phrase “a first layer formed on a second layer,” may mean that the first layer is formed over the second layer, and at least a part of the first layer may be in direct contact (e.g., direct physical and/or electrical contact) or indirect contact (e.g., having one or more other layers between the first layer and the second layer) with at least a part of the second layer.

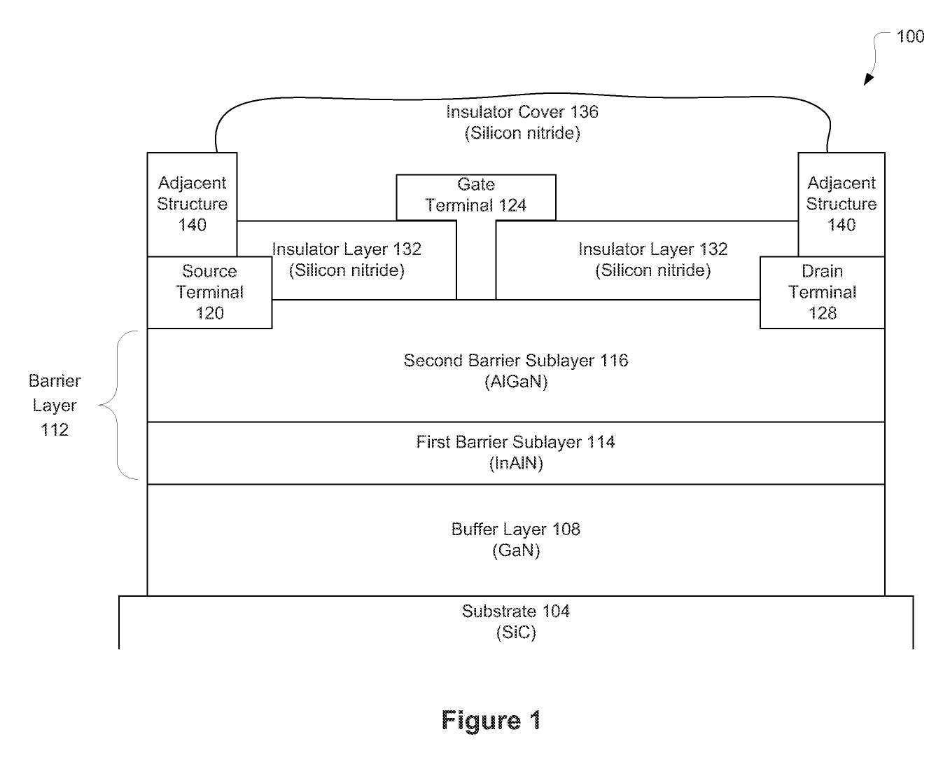

FIG. 1 schematically illustrates a cross-sectional view of a semiconductor device 100 in accordance with various embodiments of the present disclosure. The semiconductor device 100 may be, for example, a high electron mobility transistor (HEMT) device.

The semiconductor device 100 (hereinafter also referred to as “device 100”) may be fabricated on a substrate 104 that supports the device 100. The substrate 104 may comprise, for example, silicon carbide (SiC), sapphire, etc. Some of the materials of a described embodiment may be shown in the figures in parentheses. It may be noted that in other embodiments, materials other than those specifically described and/or noted in the figures may be used with appropriate modifications.

The device 100 includes a buffer layer 108 formed on the substrate 104. The buffer layer 108 may be composed of, for example, gallium nitride (GaN). The buffer layer 108 may provide an appropriate lattice structure transition between the substrate 104 and other components of the device 100, thereby acting as a buffer or isolation layer between the substrate 104 and other components of the device 100. The buffer layer 108 may be, e.g., 1-2 micrometers (μm) thick.

The device 100 also includes a barrier layer 112 having a first barrier sublayer 114 and a second barrier sublayer 116. The first barrier sublayer 114 may be formed on the buffer layer 108 and may be composed of, for example, indium aluminum nitride (InAlN). The first barrier sublayer 114 may be approximately 25 Å thick, although in various other embodiments the first barrier sublayer 114 may be other thicknesses, for example, approximately 15-30 Å thick. The composition of the first barrier sublayer 114 may complement the composition of the buffer layer 108. For example, in some embodiments, the composition of the first barrier sublayer 114 may be In_{y}Al_{1-y}N, where y is approximately 0.18. This indium concentration provides the first barrier sublayer 114 with a lattice structure that matches a lattice structure of the buffer layer 108. Such matching may result in relatively low stress, which may provide the device 100 with increased reliability through operation. While variance from an 18% concentration of indium may increase lattice structure mismatch, it may also provide desirable operating characteristics for particular embodiments. For example, decreasing the concentration of indium to 14%, for example, may induce more charge (current) but may also increase the stress in the device 100. Conversely, increasing the concentration of indium to 21%, for example, may induce less charge but may also reduce the overall stress in the device 100. In various embodiments y may be 0.14 to 0.21.

The second barrier sublayer 116 may be formed on the first barrier sublayer 114. The second barrier sublayer 116 may be composed of, for example, aluminum gallium nitride (AlGaN). In some embodiments, composition of the second barrier sublayer 116 may be AlₓGa₁₋ₓN, where x is approximately 0.2. In various embodiments x may be 0.15 to 0.22. The second barrier sublayer 116 may be doped so that it serves as a donor supply layer. In various embodiments, the second barrier sublayer 116 may be approximately 175 Å thick, although in various other embodiments, the second barrier sublayer 116 may be of other thicknesses, e.g., between approximately 150-200 Å thick.

In various embodiments, the buffer layer 108 may have a bandgap that is narrower than a bandgap of the barrier layer 112. It may be noted that the bandgaps of the sublayers may differ from one another, e.g., first barrier sublayer 114 may have a wider bandgap than that of second barrier sublayer 116, although both will be wider than the bandgap of the buffer layer 108. The difference in bandgaps in various layers of the device 100 creates a heterojunction in the device 100 that is generally at the interface of the first barrier sublayer 114 and the buffer layer 108. While in operation, a two-dimensional electron gas (2DEG) may form at the heterojunction allowing electrons to flow in a substantially two-dimensional plane through the buffer layer 108.

Providing the sublayers as shown may enable both desirable operation and reliability characteristics. For example, in addition to providing lattice-structure matching characteristics, the first barrier sublayer 114 may also provide desirable electrical characteristics, e.g., a wide bandgap, which adds charges and current to increase sheet carrier density. The increased sheet carrier density caused by the first barrier sublayer 114 may compensate for the lower percentage of aluminum in the second barrier sublayer 116. Furthermore, the second barrier sublayer 116, having the thickness and composition described, may function to maintain a sufficiently high breakdown voltage. Thus, the device 100 may employ the first barrier sublayer 114, which is a matched, wide-bandgap, InGaN sublayer, together with the second barrier sublayer 116, which is a low-stress, low-aluminium concentration sublayer, to provide high current density, high breakdown voltage, and high reliability associated with low stress.

The device 100 also includes a source terminal 120, a gate terminal 124, and a drain terminal 128. The terminals may be separated by an insulator layer 132. An insulator cover 136 may be provided over the insulator layer 132, the gate terminal 124, and adjacent structures 140. The insulator layer 132 and/or the insulator cover 136 may be comprised of a Silicon nitride.

In some embodiments, the distance between the source terminal 120 and the drain terminal 128 may be approximately 2 μm; and the gate terminal 124 may be offset from the center, defined as a point halfway between the source terminal 120 and the gate terminal 124, toward the source terminal 120, by approximately 0.25 μm.

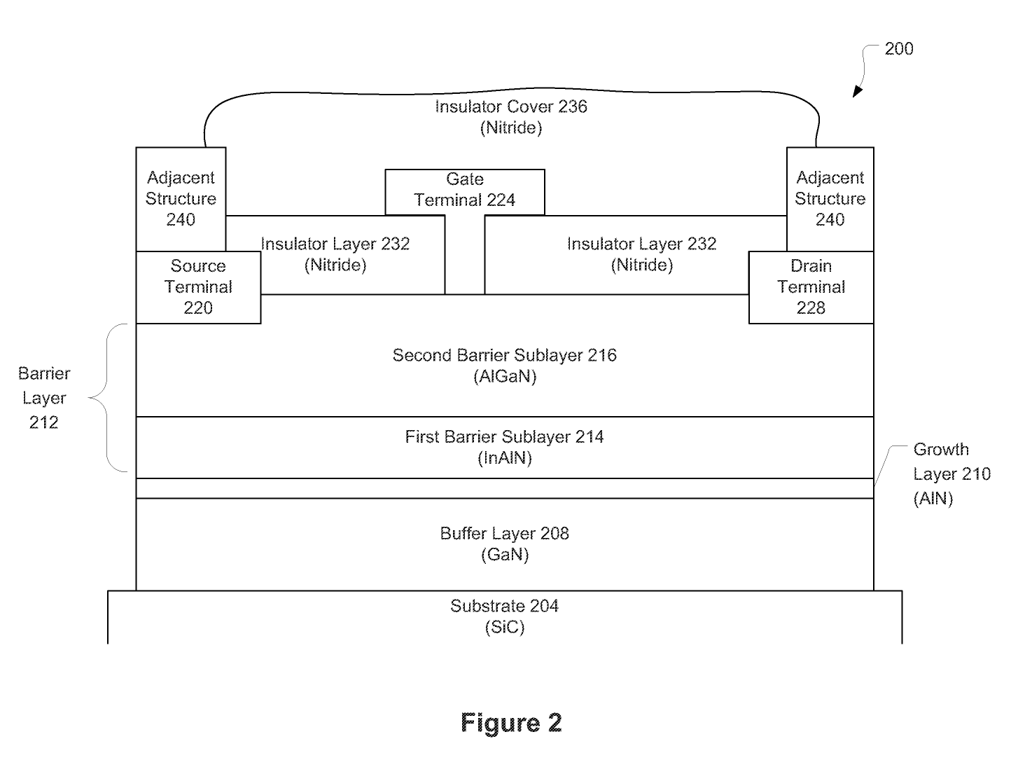

FIG. 2 schematically illustrates a cross-sectional view of a semiconductor device 200, in accordance with various embodiments of the present disclosure. The semiconductor device 200 (hereinafter also referred to as “device 200”) may be, for example, a HEMT device similar to device 100. Components of device 200 may be similar to like-named components of device 100 discussed above. However, device 200 includes a growth layer 210 disposed on the buffer layer 208. The growth layer may be composed of aluminum nitride (AlN). The growth layer 210 may be less than approximately 10 Å thick and may facilitate crystalline formation of the first barrier sublayer 214.

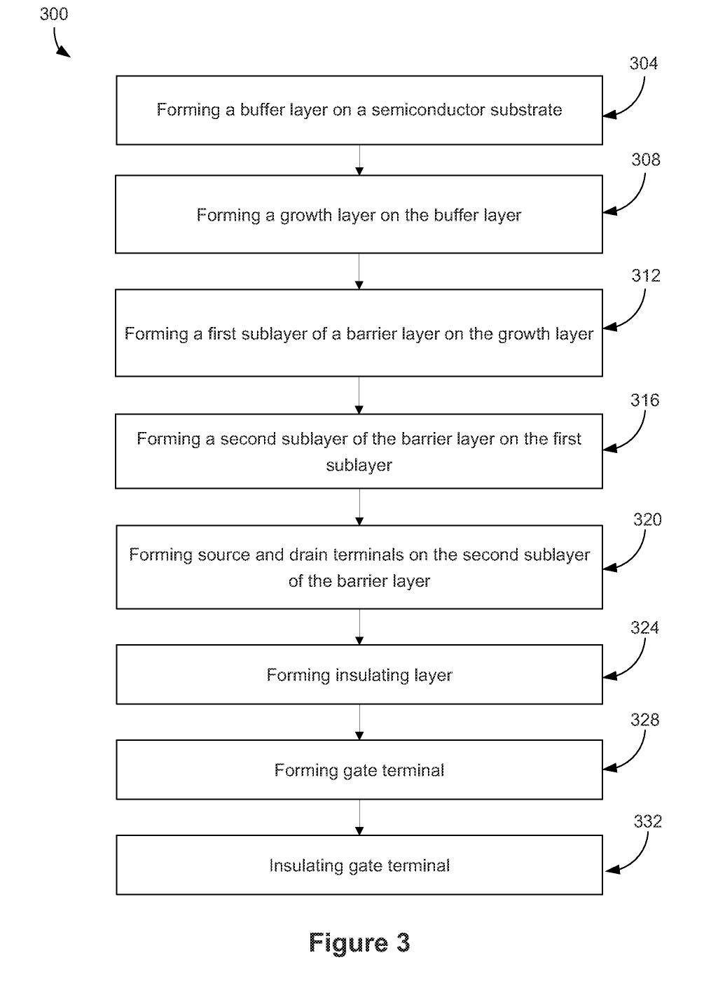

FIG. 3 illustrates a method 300 for fabricating a semiconductor device (e.g., device 100 or 200) in accordance with various embodiments of the present disclosure. The method 300 may include, at 304, forming a buffer layer (e.g., buffer layer 108 or 208) on a semiconductor substrate (e.g., substrate 104 or 204). In various embodiments, the buffer layer may be composed of GaN, and the substrate may be composed of SiC.

The method 300 may further include, at 308, forming a growth layer (e.g., growth layer 210) on the buffer layer. The growth layer may be composed of AlN and be approximately less than 10 Å thick.

The method 300 may further include, at 312, forming a first barrier sublayer (e.g., first barrier sublayer 114 or 214) of a barrier layer (e.g., barrier layer 112 or 212) on the growth layer (or on the buffer layer if the growth layer is not used as in FIG. 1). In various embodiments, the first barrier sublayer may comprise InAlN and be approximately 15-30 Å thick.

The method 300 may further include, at 316, forming a second barrier sublayer (e.g., second barrier sublayer 116 or 216) of the barrier layer on the first barrier sublayer. In various embodiments, the second barrier sublayer may comprise AlGaN and be approximately 150-200 Å thick.

The method 300 may further include, at 320, forming a source terminal (e.g., source terminal 120 or 220) and a drain terminal (e.g., drain terminal 128 or 228) on the second barrier sublayer. The source and drain terminals may be spaced apart from one another by approximately 2 μm.

The method 300 may further include, at 324, forming an insulator layer (e.g., insulator layer 132 or 232) on the second barrier sublayer, source terminal, and drain terminal.

The method 300 may further include, at 328, forming a gate terminal (e.g., gate terminal 124 or 224) through the insulator layer to contact the second barrier sublayer. The gate terminal may be formed by first etching a via through the insulator layer and then depositing the gate terminal through the via. The gate terminal may be off-centered, toward the source terminal, by approximately 0.25 μm.

The method 300 may include, at 332, insulating the gate terminal with an insulator cover (e.g., insulator cover 136 or 236).

In various embodiments, operations of the method 300 may be carried out in a different order than what is shown in FIG. 3.

Because of the various characteristics of the devices 100 and 200, discussed above, these devices may be used in a variety of applications, including, for example, in low noise amplifiers operating at microwave and millimeter wave frequencies. These devices may also be used as high-power, high-frequency transistors, as discrete transistors, and/or in integrated circuits, such as microwave monolithic integrated circuits (MMICs) used in space, military and commercial applications, mixed signal electronics, mixers, direct digital synthesizers, power digital-to-analog convertors, and/or the like.

Although the present disclosure has been described in terms of the above-illustrated embodiments, it will be appreciated by those of ordinary skill in the art that a wide variety of alternate and/or equivalent implementations calculated to achieve the same purposes may be substituted for the specific embodiments shown and described without departing from the scope of the present disclosure. Those with skill in the art will readily appreciate that the teachings of the present disclosure may be implemented in a wide variety of embodiments. This description is intended to be regarded as illustrative instead of restrictive.

What is claimed is:

1. A high electron mobility transistor (HEMT) comprising:
a buffer layer formed on a substrate, the buffer layer being composed of gallium nitride;
a barrier layer formed on the buffer layer, wherein the barrier layer includes:
a first barrier sublayer formed on the buffer layer and composed of indium aluminum nitride (InAlN); and
a second barrier sublayer formed on the first barrier sublayer and composed of aluminum gallium nitride (AlGaN); and
source, gate, and drain terminals formed on the second barrier sublayer.

2. The HEMT of claim 1, wherein the second barrier sublayer is approximately 175 angstroms thick.

3. The HEMT of claim 1, wherein the first barrier sublayer is approximately 25 angstroms thick.

4. The HEMT of claim 1 further comprising a growth layer formed on the buffer layer and between the buffer layer and the first barrier sublayer, the growth layer composed of aluminum nitride.

5. The HEMT of claim 4, wherein the growth layer is less than approximately 10 angstroms thick.

6. The HEMT of claim 1, wherein the first barrier sublayer has a lattice structure matched to a lattice structure of the buffer layer.

7. The HEMT of claim 1, wherein the second barrier sublayer comprises AlₓGa₁₋ₓN, where x is approximately 0.2.

8. The HEMT of claim 1, wherein the first barrier sublayer comprises In_{y}Al_{1-y}N, where y is approximately 0.18.

9. The HEMT of claim 1, wherein the second barrier sublayer comprises AlₓGa₁₋ₓN, where x is approximately 0.2, the first barrier sublayer is approximately 25 angstroms and comprises In_{y}Al_{1-y}N, where y is approximately 0.18.

10. The HEMT of claim 1, wherein the first barrier sublayer comprises In_{y}Al_{1-y}N, where y is between approximately 0.14 and 0.21; and the second barrier sublayer comprises AlₓGa₁₋ₓN, where x is between approximately 0.15 and 0.22.

11. The HEMT of claim 1, wherein the first barrier sublayer has a thickness that is approximately 15-30 angstroms and the second barrier sublayer has a thickness that is approximately 150-200 angstroms.

12. The HEMT of claim 1, wherein:
the first barrier sublayer has a thickness that is approximately 15-30 angstroms and comprises In_{y}Al_{1-y}N, where y is between approximately 0.14 and 0.21; and
the second barrier sublayer has a thickness that is approximately 150-200 angstroms and comprises AlₓGa₁₋ₓN, where x is between approximately 0.15 and 0.22.

13. The HEMT of claim 1, wherein a distance between the source terminal and the drain terminal is approximately 2 micrometers.

14. The HEMT of claim 1, wherein the gate terminal is offset from a point halfway between the source terminal and the gate terminal, toward the source terminal, by approximately 0.25 micrometers.

15. A method of fabricating a semiconductor device on a semiconductor substrate, the method comprising:
forming a buffer layer on the semiconductor substrate;
forming a first barrier sublayer on the buffer layer, the first barrier sublayer composed of indium aluminum nitride;
forming a second barrier sublayer on the first barrier sublayer, the second barrier sublayer composed of aluminum gallium nitride; and
forming a gate terminal, a source terminal, and a drain terminal on the second barrier sublayer.

16. The method of claim 15, wherein said forming the second barrier sublayer comprises:
forming the second barrier sublayer to be approximately 150-200 angstroms thick.

17. The method of claim 15, wherein said forming the first barrier sublayer comprises:
forming the first barrier sublayer to be approximately 15-30 angstroms thick.

18. The method of claim 15, further comprising:
forming a growth layer on the buffer layer, and forming the first barrier sublayer on the growth layer, wherein the growth layer is composed of aluminum nitride.

19. The method of claim 18, wherein said forming the growth layer comprises:
forming the growth layer to be less than approximately 10 angstroms thick.

20. The method of claim 18, wherein said forming the first and second sublayers comprises:
forming the first barrier sublayer to be composed of In_{y}Al_{1-y}N, where y is 0.14 to 0.21; and
forming the second barrier sublayer to be composed of AlₓGa₁₋ₓN, where x is 0.15 to 0.22.
